(19) United States
(12) Patent Application Publication
(10) Pub. No.: US 2022/0381885 A1
(43) Pub. Date: Dec. 1, 2022

(54) LIDAR TRANSMITTER, SYSTEM AND METHOD

(71) Applicant: AMS SENSORS ASIA PTE. LTD, Singapore (SG)

(72) Inventors: Dominik Ruck, Graz (AT); Ho Hoai Duc Nguyen, Munich (DE); Michiel Helsloot, Eindhoven (NL)

(73) Assignee: ams Sensors Asia Pte. Ltd, Singapore (SG)

(21) Appl. No.: 17/775,012

(22) PCT Filed: Nov. 5, 2020
(86) PCT No.: PCT/SG2020/050638

§ 371 Date: May 6, 2022

Related U.S. Application Data
(60) Provisional application No. 62/931,270, filed on Nov. 6, 2019.

(51) Int. Cl. G01S 7/481; G01S 17/931

(52) U.S. Cl. CPC G01S 7/4815; G01S 7/4816; G01S 17/931

(57) ABSTRACT

A LIDAR transmitter system comprising an array of laser energy sources, each laser energy source comprising a corresponding photodetector. The laser energy sources are configured to emit laser energy towards a LIDAR target. Each respective photodetector is configured to detect the laser energy emitted by a corresponding energy source of the array.

### TECHNICAL FIELD OF THE DISCLOSURE

The disclosure relates to LIDAR system and methods, particularly but not exclusively, to a LIDAR transmitter system, a LIDAR system, and a method for emitting a LIDAR signal.

### BACKGROUND OF THE DISCLOSURE

LIDAR is a technique of measuring a distance to a target. The target is illuminated with laser light and the reflected laser light is detected with a sensor. A time-of-flight measurement is made to establish the distance between the LIDAR system and different points on the target to build up a three-dimensional representation of the target.

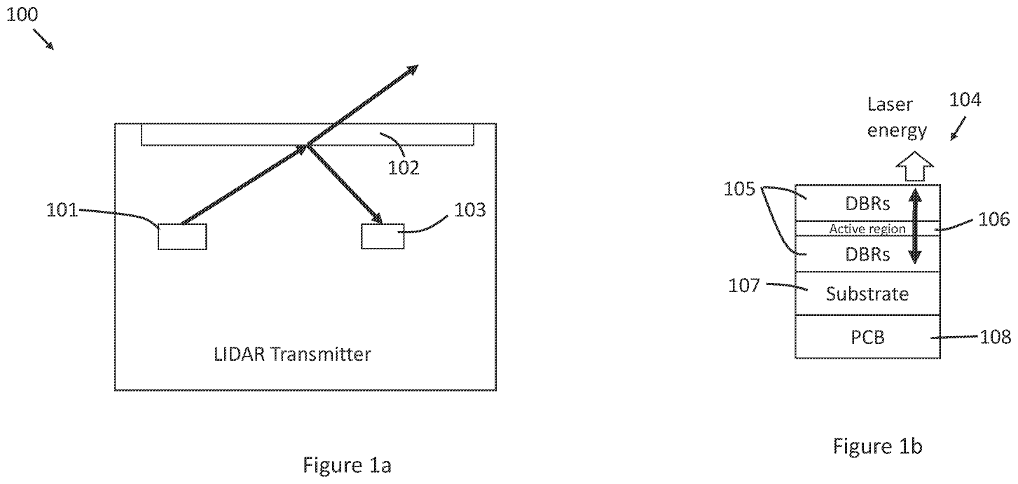

An example of a known LIDAR transmitter system 100 is illustrated in FIG. 1a. The known LIDAR transmitter system 100 includes a vertical-cavity surface-emitting laser (VCSEL) array 101 which emits laser energy through a lens or cover glass 102. A portion of the emitted laser energy reflects off the inner surface of the lens or cover glass 102 or is diverted by prisms, mirrors, or other optical components with moving parts and/or mechanical motors arranged in the beam path. This portion of diverted laser energy is received by an external detector 103. The term external is used herein to mean external to the VCSEL array 101. The external detector 103 determines the intensity of the output beam of the VCSEL array by generating an output signal voltage or current based on the detected beam. If the output signal voltage or current of the external detector 103 changes (for example, drops), it is a possible indication that the VCSEL array is not correctly functioning.

The VCSEL array 101 of FIG. 1a may comprise a plurality of known VCSELs of the type illustrated in FIG. 1b. In the VCSEL 104 of FIG. 1b, a plurality of distributed Bragg reflector (DBR) layers 105 are positioned on either side of an active region 106, for example comprising one or more quantum wells, for laser energy generation and resonance between the DBR layers 105. These DBR layers 105 and active region 106 may be arranged on a substrate 107, which in turn may be arranged on a printed circuit board 108 (PCB). The VCSEL 104 of FIG. 1b is a top-emitting VCSEL however bottom-emitting VCSELs are also known.

Some problems associated with known LIDAR transmitter systems 100 of the type shown in FIG. 1a using VCSELs of the type shown in FIG. 1b are:

(i) The fluctuation in the output signal voltage or current from the external detector 103 can be very high, making it difficult to establish a cause of malfunction of the LIDAR transmitter. For example, a fluctuating output signal may be caused by any one of: a prism, mirror or other optical component becoming misaligned (for example due to a moving component or motor breaking down), individual VCSELs malfunctioning and/or having reduced efficiency due to aging effects. It is very challenging to establish which of these is the cause of a transmitter malfunction based solely on the output signal current or voltage of the external detector 103.

(ii) The output signal voltage or current from the external detector 103 cannot determine the presence of hot or dark spots in the output beam. The terms hot spot and dark spot are used herein to portions of an output beam which have respectively higher or lower power than the rest of the beam.

(iii) The output signal voltage or current from the external detector 103 cannot distinguish between the output of individual emitters of the array.

It is an aim of the present disclosure to provide a LIDAR transmitter system, LIDAR system, and a method for emitting a LIDAR signal that addresses one or more of the problems above or at least provides a useful alternative.

### SUMMARY

In general terms, this disclosure proposes to overcome the above problems by arranging a photodetector with each laser energy source of the laser energy source array of the LIDAR transmitter system. This arrangement provides at least one or more of the following advantages over known LIDAR transmitter systems:

(i) With a photodetector arranged with each laser energy source, there are no prisms, mirrors or other optical components, or moving parts. Thus, any change in output signal voltage or current from the photodetectors can be immediately attributed to the laser energy sources rather than to any other component of the array. For example, when a drop in one or more photodetector outputs is detected, its cause can be directly attributed to a malfunction or decrease in efficiency in that corresponding laser energy source rather than to a problem with a prism, mirror, or other component of the transmitter.

(ii) Together, the output signal voltages or currents of the photodetectors provide a much higher resolution or granularity with which to monitor the array, for example up to individual emitter resolution. This permits, for example, the detection of hot (i.e. high intensity) or dark (i.e. low intensity) spots in the energy output to be made accurately and efficiently. If required, the detected hot or dark spots can also be compensated for more effectively than in known transmitter systems by controlling the corresponding laser energy source or laser energy sources of the array at the same, higher resolution. A scenario where this may be particularly useful is where a LIDAR transmitter system is required to output a high power beam when visibility is low in mist or fog. In such a scenario, any unexpected hot spots in the higher power beam could result in a risk to eye safety so monitoring the output beam is important. With the LIDAR transmitter system disclosed herein, the hot spots can immediately be compensated for by deactivating or reducing the output of laser energy sources contributing to the hotspots. Arranging a photodetector with each laser energy source of the array thus provides a means to guarantee eye safety and functional safety at higher power operation.

(iii) The malfunction or failure of individual emitters and/or rows or columns of emitters can be established more easily because any change in output signal voltage or current from individual photodetectors, or rows or columns thereof may directly indicate that the corresponding emitter and/or row of column of emitters is malfunctioning and/or not working as intended.

(iv) By integrating the respective photodetectors into the laser energy sources, any stray energy propagating in the array that could interfere with the LIDAR operation can be detected and compensated for. For example, if internal reflections and/or other noise can be measured at emitter level resolution at the transmitter, a much wider variety of noise reducing algorithms become available to use on the output of a corresponding LIDAR receiver. The photodetectors thus provide a powerful, built-in diagnostic tool not available in a transmitter system with an external detector.

(v) With space in LIDAR systems being at a premium, integrating the respective photodetectors into the laser energy sources reduces the reliance on prisms, optical components, motors and/or other moving parts all of which take up valuable space.

According to one aspect of the present disclosure, there is provided a LIDAR transmitter system comprising: an array of laser energy sources, each laser energy source comprising a corresponding photodetector, wherein the laser energy sources are configured to emit laser energy towards a LIDAR target, and wherein each respective photodetector is configured to detect the laser energy emitted by a corresponding energy source of the array.

Optionally, the array of laser energy sources comprises an array of vertical cavity surface emitting lasers (VCSELs) arranged on a wafer.

Optionally, each respective photodetector is arranged in, on or under a respective VCSEL.

Optionally, each VCSEL comprises a resonator comprising a first reflector at a first end and a second reflector at a second end opposite the first end, the laser energy emitted towards the LIDAR target is emitted from the first end, and the laser energy detected by the photodetector is emitted from the second end.

Optionally, the first and second reflectors comprise distributed Bragg reflectors.

Optionally, each respective photodetector comprises a photodiode arranged in, on or under a corresponding second reflector.

Optionally, the LIDAR transmitter system comprises a processor configured to: calculate a two-dimensional energy intensity profile of the array of laser energy sources from an output of the photodetectors; and determine from the two-dimensional energy intensity profile the presence of one or more energy intensity hot spots, energy intensity dark spots, and/or malfunctioning laser energy sources.

Optionally, the processor is configured to: control one or more of the laser energy sources to compensate for said energy intensity hots spots, energy intensity dark spots, and/or malfunctioning laser energy sources by: activating, deactivating, increasing and/or decreasing the energy output of one or more of the laser energy sources.

Optionally, each photodetector is configured to detect laser energy emitted from one or more other laser energy sources of the array of laser energy sources.

Optionally, the laser energy sources comprise edge emitters, LEDs and/or integrated laser energy sources.

According to a second aspect of the present disclosure, there is provided a LIDAR system, the LIDAR system comprising: the LIDAR transmitter system described above; and a LIDAR receiver system.

Optionally, the LIDAR system is configured to receive information from the LIDAR receiver system, combine said information with an output of the photodetectors, and control one or more of the laser energy sources by: activating, deactivating, increasing and/or decreasing the energy output of one or more of the laser energy sources.

Optionally, said information comprises driving condition information of a vehicle and/or ambient or environmental lighting information.

According to a third aspect of the present disclosure, there is provided a method for emitting laser energy towards a LIDAR target, the method comprising: emitting laser energy from an array of laser energy sources, each laser energy source comprising a photodetector;
with each respective photodetector, detecting laser energy emitted by a respective laser energy source; calculating a two-dimensional energy intensity profile of the array of laser energy sources from the respective outputs of the photodetectors; determining from the two-dimensional energy intensity profile the presence of one or more energy intensity hot spots, energy intensity dark spots, and/or malfunctioning laser energy sources; and controlling one or more of the laser energy sources to compensate for said energy intensity hots spots, energy intensity dark spots, and/or malfunctioning laser energy sources by: activating, deactivating, increasing and/or decreasing the energy output of one or more of the laser energy sources.

Optionally, the array of laser energy sources comprises an array of VCSELs arranged on a wafer.

Optionally, each respective photodetector comprises a photodetector arranged in, on or under a respective VCSEL.

Thus, embodiments of this disclosure provide the above described advantages.

### BRIEF DESCRIPTION OF THE PREFERRED EMBODIMENTS

Some embodiments of the disclosure will now be described by way of example only and with reference to the accompanying drawings, in which:

FIG. 1a illustratively shows a known LIDAR transmitter.

FIG. 1b illustratively shows a known VCSEL.

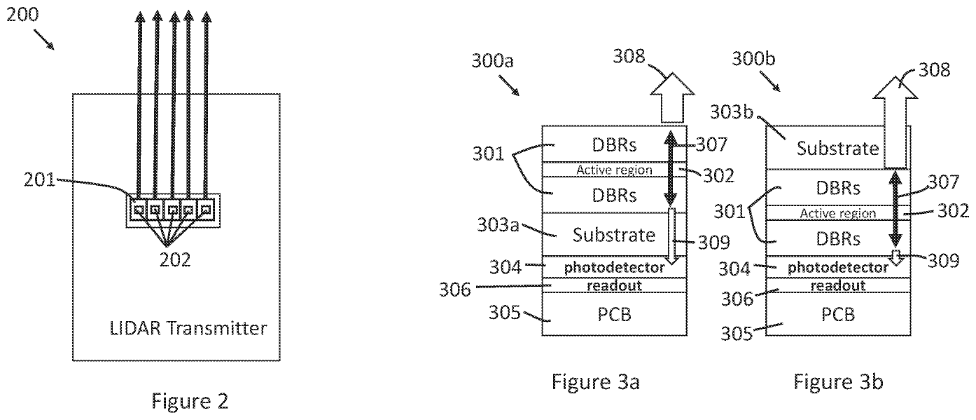

FIG. 2 illustratively shows a LIDAR transmitter system in accordance with the present disclosure.

FIG. 3a illustratively shows a VCSEL in accordance with the present disclosure.

FIG. 3b illustratively shows a VCSEL in accordance with the present disclosure.

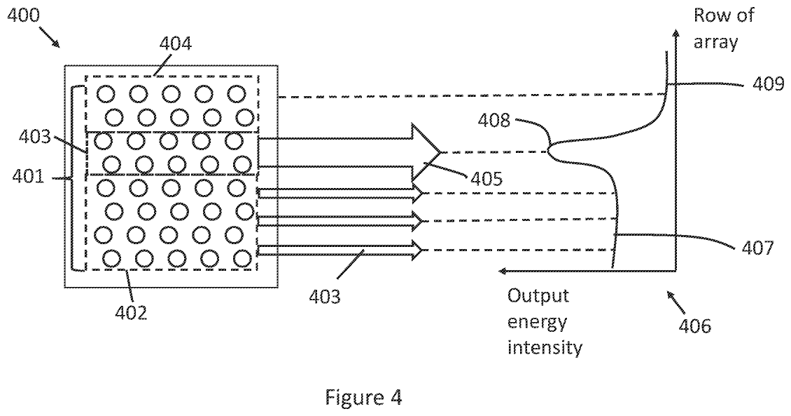

FIG. 4 illustratively shows an array of laser energy sources and output energy intensity profile in accordance with the present disclosure.

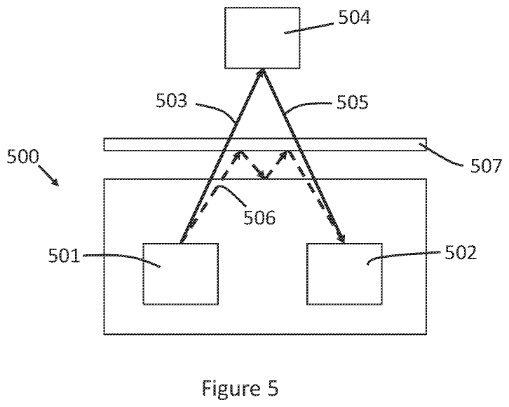

FIG. 5 illustratively shows a LIDAR system in accordance with the present disclosure.

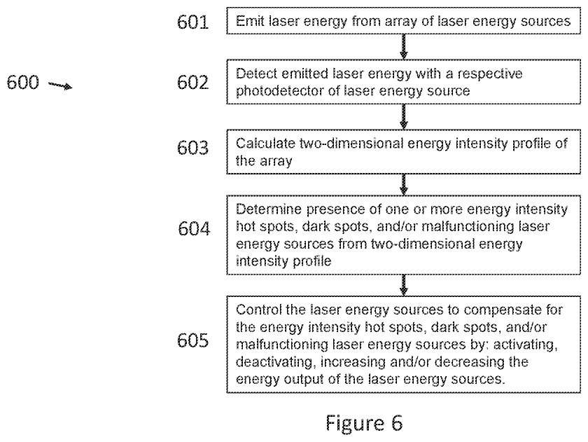

FIG. 6 shows a flowchart showing method steps in accordance with the present disclosure.

### DETAILED DESCRIPTION OF THE PREFERRED EMBODIMENTS

In general terms, this disclosure provides a LIDAR transmitter system comprising an array of laser energy sources each comprising a corresponding photodetector. The photodetectors together provide a means to measure laser energy output at an individual emitter resolution and thus provide a means to more accurately measure and control the output of the array compared to known LIDAR transmitter systems.

Some examples of the solution provided by this disclosure are given in the accompanying figures.

FIG. 2 shows an illustration of a LIDAR transmitter system 200 comprising an array 201 of laser energy sources. Each laser energy source of the array 201 comprises a photodetector 202. Each photodetector 202 is configured to detect laser energy emitted by a respective laser energy source, thereby providing the emitter level measurement and control resolution described above.

Whilst an array of VCSELs is described herein as the array laser energy sources, it is envisaged that the present disclosure is equally applicable to any array of laser energy sources suitable for use with a LIDAR transmitter system such as arrays of edge emitters, integrated laser sources, LEDs and/or any combination thereof alone or together with VCSELs.

As described above, the array 201 of laser energy sources may comprise an array of VCSELs. The array of VCSELs may be arranged on a wafer and may be manufactured in an epitaxial process or integrated using wafer-bonding

FIGS. 3a and 3b illustrate different VCSEL structures 300a, 300b which may be used in the LIDAR transmitter 200 of FIG. 2 to provide the array 201 of laser energy sources. In the example VCSEL structures 300a, 300b of FIGS. 3a and 3b, a plurality of distributed Bragg reflector (DBR) layers 301 are arranged on either side of an active region 302 to provide a resonator for laser energy generation 307. The resonator may thus be said to comprise a first reflector at a first end of the resonator and a second reflector at a second end of the resonator opposite the first end. The reflectance and corresponding efficiency of the DBR layers 301 is configured such that a first fraction 308 of the laser energy generated by the resonator is emitted from the first end towards a LIDAR target, and a second, smaller fraction 309 of the laser energy generated by the resonator is emitted from the second end and detected by the photodetector 304. For example, the first reflector may be configured as an output coupler having a high transmissivity for the laser radiation wavelength and the second reflector may be similarly configured as an output coupler but it may have a smaller transmissivity for the laser radiation wavelength. In this way, only a small fraction of the generated laser energy is lost to the photodetector and the output laser energy emitted towards the LIDAR target remains high enough to be suitable for use with LIDAR systems. Typically, the fraction 309 of generated laser energy light emitted through the second reflector is determined by the sensitivity of the corresponding photodetector 304. For example, the higher the photodetector 304 sensitivity, the smaller the fraction 309 of laser energy the second reflector needs to emit for it to detected by the photodetector 304. Conversely, if a photodetector 304 with lower sensitivity is used (for example, because it is cheaper), a larger fraction 309 may need to be emitted through the second reflector for detection by the photodetector 304.

The photodetector 304 may be arranged in, on or under one or more of the other layers of the VCSEL. The example shown in FIG. 3a shows a top emitting VCSEL where the output laser energy 309 to be detected by the photodetector 304 is emitted through a wafer substrate 303a on which the DBR layers 301 and active region 302 are arranged. In contrast, the example of FIG. 3b shows a bottom emitting VCSEL where the output laser energy 308 for use as the LIDAR signal is emitted through the wafer substrate 303b. It will be appreciated that other configurations and layer orders fall within the scope of the appended claims and that the layer orders described herein are exemplary.

All of the above described layers may further be arranged on a printed circuit board (PCB) 305 optionally connected by one or more readouts 306. The readouts 306 may comprise one or more electrical contacts to provide an interface to one or more processors configured to receive the photodetector output signals and/or control the VCSEL driving voltage or current signals applied through the electrical contacts. The interface provided hereby may comply with one or more known international standards and may be for example, a Mobile Industry Processor Interface (MIPI) interface. Typically, VCSELs in an array are addressable (i.e. controllable) on a column or row level however it is envisaged that they may also be addressed individually, or by region.

In both the examples of FIGS. 3a and 3b, the printed circuit board 305 and readout 306 are arranged on the photodetector side of the VCSEL to reduce the need for complex circuit arrangements. Alternatively, in some examples, the photodetector 304 may be positioned above the DBR layers, in the DBR layers or in the active region of the VCSEL. In these cases, the photodetector 304 and readout 306 are configured not to interfere with laser energy generation and additional circuit elements and contacts may be required to route the photodetector 304 output signals to the one or more processors.

Each photodetector 304 may comprise a photodiode, such as a pin diode, single photon avalanche diode, avalanche diode, or phototransistor.

The above described VCSEL layers and photodetectors may be formed and integrated as part of a single wafer manufacturing process, thus simplifying the manufacturing requirements of the LIDAR transmitter because no additional external components are required. For example, the VCSEL layers and photodetectors may be grown epitaxially or the photodetectors may be integrated into the VCSEL using wafer-bonding.

The array 201 of FIG. 2 described above may be formed from a plurality of the above described VCSELs 300a, 300b. As described above, the output of each photodetector provides a means to monitor and control the output of the array 201 at an emitter level resolution without the need for external components such as prisms, mirrors and/or other components such as mechanical motors and/or external sensors.

FIG. 4 illustratively shows an array 400 of laser energy sources 401, for example VCSELs 300a, 300b of the type described above in connection with FIGS. 3a and 3b, for use with a LIDAR transmitter system 200 such as that shown in FIG. 2. Whilst the array 400 in FIG. 4 is shown to have a specific pattern and number of VCSELs, it is envisaged that any suitable pattern and number of VCSELs may be used based on the requirements of the LIDAR transmitter system in which the array 400 is to be used.

The beam output by the array 400 may in some instances have one or more energy intensity hot spots and/or energy intensity dark spots caused by, for example, one or more malfunctioning laser energy sources 401. In the illustrative example of FIG. 4. The laser energy sources 401 in a first region 402 of the array 400 are functioning correctly and their contribution 403 to the output beam is measured by the corresponding photodetectors in the array 400 to be as intended. However, the laser energy sources 401 in a second region 403 of the array 400 are malfunctioning and have a much higher output intensity 405 than intended, resulting in an energy intensity hot spot in the output beam. The laser energy sources 401 in a third region 404 of the array 400 are also malfunctioning and are not outputting any energy, resulting in an energy intensity dark spot in the output laser beam.

Unlike in the case of known LIDAR transmitter systems which have an external detector and for which it would not be possible to distinguish between malfunctioning and/or correctly functioning individual laser energy sources, the presence of a photodetector for each laser energy source provides a diagnostics tool to determine, for example, that the laser energy sources 401 in the first region 402 are functioning correctly, but that the laser energy sources 401 in the second and third regions 403, 404 are not. This determination may be made on an individual laser energy source level resolution, on a row/column level resolution, and/or on a region level resolution as is shown in the example of FIG. 4.

FIG. 4 further shows an exemplary, energy intensity profile 406 of the array 400 calculated from the output signals of the photodetectors of the laser energy sources in the three regions 402, 403, 404 described above. The signals output by the photodetectors may be received by a processor through an interface such as the MIPI interface described above. The processor is configured to calculate the energy intensity profile from the output signals.

In the example of FIG. 4, the output energy intensity from the first region 402 of the array 400 corresponds to a first plateau 407 in the profile, the output energy intensity from the second region 403 of the array 400 (i.e. the hotspot) corresponds to a peak 408 in the profile, and the output energy intensity from the third region 404 of the array 400 (i.e. the dark spot) corresponds to a second plateau 409 in the profile having much lower intensity than the first plateau 407.

From the example energy intensity profile of FIG. 4, it may be determined that the laser energy sources in the first region 402 are functioning correctly but that the laser energy sources in second and third regions 403, 404 are not. This determination is made without any external sensor, prism, mirror, or other components directing part of the output beam to the external sensor. In order to compensate for the incorrectly functioning laser energy sources in the second and third regions 403, 404, the laser energy sources in these regions may be controlled by, for example, changing the applied driving voltage or current signals to the laser energy sources in these regions.

For example, the laser energy sources in the second region 403 which produce a hot spot may be controlled to decrease output or be deactivated to compensate for or eliminate the hotspot. This could be achieved by reducing the driving current or voltage. Similarly, the laser energy sources in the third region 404 which produce a dark spot may be controlled to increase output (and/or the output laser energy sources in neighbouring rows, columns, regions or at individual level may be increased if the emitters causing the dark spot are dead and their output cannot be increased). This may be achieved by increasing the driving current or voltage. In this way, the hot spots and dark spots in the output beam and/or malfunctioning emitters can be compensated for accurately and without the need for any external sensors or other components.

Whilst the energy intensity profile 406 shown in the example of FIG. 4 shows output energy intensity against row number of the array, it is also envisaged that profiles of output energy intensity against column number and/or individual emitter number may be calculated to provide a complete two-dimensional profile or map of the output energy intensity of the array. The two-dimensional profile can be used as described above to control the output of rows, columns or individual emitters to accurately and efficiently control the output LIDAR signal. In this way, eye safety and functional safety of higher powered beams is significantly improved and any risks (e.g. due to hotspots in the beam) are minimised.

FIG. 5 illustratively shows a LIDAR system 500 comprising a LIDAR transmitter system 501 such as that described above in connection with FIGS. 2-4 and a LIDAR receiver system 502. The LIDAR transmitter system 501 is configured to emit laser energy 503 towards a LIDAR target 504. Reflected laser energy 505 propagates towards the LIDAR receiver system 502 where it is detected and used to calculate a distance from the LIDAR system 500 to the target, for example using a time-of-flight calculation.

The LIDAR system 500 may operate as a flash LIDAR where the LIDAR transmitter system 501 emits laser pulses (for example sub-nanosecond light pulses), or as a scanning LIDAR where the LIDAR transmitter system 501 emits a continuous, directed beam.

The LIDAR receiver system 502 may comprise a plurality of photodetectors, for example photodiodes, such as pin diodes, single photon avalanche diodes, avalanche diodes, or phototransistors configured to detect the laser energy reflected from the LIDAR target. Each photodetector of the LIDAR receiver system 502 acts as a detection pixel typically corresponding to one emitter in the array of the LIDAR transmitter system 501. The one-to-one pixel-emitter correspondence may be used to calculating a time-of-flight histogram which may be used to detect and compensate for any internal reflections 506 from, for example, optional cover glass 507 of the LIDAR system 500, or any cross-talk between laser energy sources of the array and a plurality of different detection pixels.

Typically, the signals detected by the LIDAR receiver system 502 show some fluctuation which may be caused by, for example, the above described hot spots, dark spots, and/or malfunctioning emitters, or by noise, internal reflections, cross-talk and/or other interference. In known LIDAR systems, it is difficult to determine when a fluctuation at a LIDAR receiver system pixel is due to noise, cross-talk or other interference, malfunctions or dead emitters in the LIDAR transmitter system. In known systems, it can thus be difficult to establish what actions need to be taken to improve the gain of the system. In contrast, the LIDAR system 500 provided herein may solve this problem by combining the output signal of the photodetectors in each laser energy source of the LIDAR transmitter system 501 with information received from the LIDAR receiver system 502 to provide automatic gain control.

For example, information from the LIDAR receiver system 502 indicating that a detection pixel has a weak detection signal may be combined with information from the photodetectors of the LIDAR transmitter system 501 indicating that the output beam has a dark spot corresponding to that detection pixel. The driving voltage or current to one or more laser energy sources may consequently be increased to eliminate the dark spot, improving the detection signal at the detection pixel.

Conversely, information from the LIDAR receiver system 502 indicating that one or more detection pixels are showing very strong signals may be combined with information from the photodetectors of the LIDAR transmitter system 501 indicating the presence of a hotspot in the output beam which is causing significant cross-talk. The driving voltage or current to one or more laser energy sources may consequently be decreased to eliminate the hot spot, reducing the cross-talk effect at the detection pixels.

The above described examples of automatic gain control provided by combining information received from the LIDAR receiver system 502 with the output of the photodetectors of the LIDAR transmitter system 501 are not intended to be limiting and it will be appreciated that other scenarios and combinations of receiver information being combined with light source photodetector output fall within the scope of the appended claims.

For example, the information received from the LIDAR receiver system 502 may comprise driving condition information of a vehicle on which the LIDAR system 500 is mounted and/or ambient or environmental lighting information. Thus, if driving conditions are bad (for example because visibility is low due to fog, mist, or adverse ambient or environmental lighting), this information may be used to increase the power of the output beam of the LIDAR transmitter system 501 to compensate. In this way, the power of the output beam may be controlled dynamically.

FIG. 6 shows a flowchart showing method steps in accordance with the present disclosure. In general terms, the method is directed to emitting laser energy towards a LIDAR target and may be used in connection with the above described LIDAR transmitter system and LIDAR system. The method 600 comprises emitting 601 laser energy from an array of laser energy sources, each laser energy source comprising a photodetector. The array of energy sources may optionally comprise VCSELs as described herein. The photodetectors may optionally be arranged in, on, or under respective VCSELs. The laser energy emitted by each of the laser energy sources is detected 602 with a respective photodetector. A two-dimensional energy intensity profile of the array of laser energy sources is calculated 603 from the respective outputs of the photodetectors. The presence of one or more energy intensity hot spots, energy intensity dark spots, and/or malfunctioning laser energy sources is determined 604 from the two-dimensional energy intensity profile. One or more of the laser energy sources are controlled 605 to compensate for said energy intensity hots spots, energy intensity dark spots, and/or malfunctioning laser energy sources by: activating, deactivating, increasing and/or decreasing the energy output of one or more of the laser energy sources. As described above in relation to FIGS. 2-5, the method ensures eye safety and functional safety of higher powered beams is significantly improved and any risks (e.g. due to hotspots in the beam) are minimised without the need for external sensors, prisms, mirrors, or other components.

Embodiments of the present disclosure can be employed in many different applications including, for example, for 3D facial recognition, proximity detection, presence detection, object detection, distance measurements, and/or collision avoidance for example in the field of automotive vehicles or drones, and other fields and industries.

### LIST OF REFERENCE NUMERALS

100 known LIDAR transmitter system
101 VCSEL array
102 lens or cover glass
103 external detector
104 VCSEL
105 distributed Bragg reflector layers (DBRs)
106 active region
107 substrate
108 printed circuit board (PCB)
200 LIDAR transmitter system
201 array of laser energy sources
202 photodetector
300a VCSEL structure
300b VCSEL structure
301 distributed Bragg reflector layers (DBRs)
302 active region
303a substrate
303b substrate
304 photodetector
305 printed circuit board (PCB)
306 readout
307 laser energy generation
308 fraction of laser energy emitted towards LIDAR target
309 fraction of laser energy emitted towards photodetector
400 array of laser energy sources
401 laser energy sources
402 first region
403 second region
404 third region
405 high output intensity
406 energy intensity profile
407 first plateau
408 peak
409 second plateau
500 LIDAR system
501 LIDAR transmitter system
502 LIDAR receiver system
503 laser energy emitted towards a LIDAR target
504 LIDAR target
505 reflected laser energy
506 internal reflections
507 cover glass
600 method
601 emitting
602 detecting
603 calculating
604 determining
605 controlling

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

1. A LIDAR transmitter system comprising:
an array of laser energy sources, each laser energy source comprising a corresponding photodetector, wherein the laser energy sources are configured to emit laser energy towards a LIDAR target, and wherein each respective photodetector is configured to detect the laser energy emitted by a corresponding energy source of the array.

2. The LIDAR transmitter system according to claim 1, wherein the array of laser energy sources comprises an array of vertical cavity surface emitting lasers (VCSELs) arranged on a wafer.

3. The LIDAR transmitter system according to claim 2, wherein each respective photodetector is arranged in, on or under a respective VCSEL.

4. The LIDAR transmitter system according claim 3,
wherein each VCSEL comprises a resonator comprising a first reflector at a first end and a second reflector at a second end opposite the first end,
wherein the laser energy emitted towards the LIDAR target is emitted from the first end, and wherein the laser energy detected by the photodetector is emitted from the second end.

5. The LIDAR transmitter system according to claim 4, wherein the first and second reflectors comprise distributed Bragg reflectors.

6. The LIDAR transmitter according to claim 5, wherein each respective photodetector comprises a photodiode arranged in, on or under a corresponding second reflector.

7. The LIDAR transmitter system according to claim 1, comprising a processor configured to:
calculate a two-dimensional energy intensity profile of the array of laser energy sources from an output of the photodetectors; and
determine from the two-dimensional energy intensity profile the presence of one or more energy intensity hot spots, energy intensity dark spots, and/or malfunctioning laser energy sources.

8. The LIDAR transmitter system according to claim 7, wherein the processor is configured to:
control one or more of the laser energy sources to compensate for said energy intensity hots spots, energy intensity dark spots, and/or malfunctioning laser energy sources by: activating, deactivating, increasing and/or decreasing the energy output of one or more of the laser energy sources.

9. The LIDAR transmitter system according to claim 1, wherein each photodetector is configured to detect laser energy emitted from one or more other laser energy sources of the array of laser energy sources.

10. The LIDAR transmitter system according to claim 1, wherein the laser energy sources comprise edge emitters, LEDs and/or integrated laser energy sources.

11. A LIDAR system, the LIDAR system comprising:
the LIDAR transmitter system of claim 1; and
a LIDAR receiver system.

12. (canceled)

12. (canceled)

13. A method for emitting laser energy towards a LIDAR target, the method comprising:
emitting laser energy from an array of laser energy sources, each laser energy source comprising a photodetector;
with each respective photodetector, detecting laser energy emitted by a respective laser energy source;
calculating a two-dimensional energy intensity profile of the array of laser energy sources from the respective outputs of the photodetectors;
determining from the two-dimensional energy intensity profile the presence of one or more energy intensity hot spots, energy intensity dark spots, and/or malfunctioning laser energy sources; and
controlling one or more of the laser energy sources to compensate for said energy intensity hots spots, energy intensity dark spots, and/or malfunctioning laser energy sources by: activating, deactivating, increasing and/or decreasing the energy output of one or more of the laser energy sources.

14. The method according to claim 13, wherein the array of laser energy sources comprises an array of VCSELs arranged on a wafer.

15. The method according to claim 14, wherein each respective photodetector comprises a photodetector arranged in, on or under a respective VCSEL.

16. The LIDAR system according to claim 11, wherein the LIDAR system is configured to receive information from the LIDAR receiver system, combine said information with an output of the photodetectors, and control one or more of the laser energy sources by: activating, deactivating, increasing and/or decreasing the energy output of one or more of the laser energy sources.

17. The LIDAR system according to claim 11, wherein said information comprises driving condition information of a vehicle and/or ambient or environmental lighting information.
